(19) United States
(12) Patent Application Publication
(10) Pub. No.: US 2026/0302970 A1
(43) Pub. Date: Oct. 1, 2026

(54) METHOD FOR DETECTING THE PRESENCE OR ABSENCE OF A NEUTRAL CONDUCTIVE LINE IN A MULTIPHASE AC VOLTAGE SOURCE

(71) Applicant: SCHAEFFLER TECHNOLOGIES AG & CO. KG, Herzogenaurach (DE)

(72) Inventors: Jérôme LACHAIZE, Toulouse (FR); Morgan DROUYER, Seysses (FR)

(73) Assignee: SCHAEFFLER TECHNOLOGIES AG & CO. KG, Herzogenaurach (DE)

(21) Appl. No.: 19/490,995

(22) PCT Filed: Jun. 10, 2024
(86) PCT No.: PCT/EP2024/065869

§ 371 Date: Dec. 8, 2025

(30) Foreign Application Priority Data
Jun. 13, 2023 (FR) FR2305948

(51) Int. Cl. H02M 7/797; B60L 53/30; B60L 53/62; G01R 19/165; G01R 23/00; H02M 1/42

(52) U.S. Cl. CPC H02M 7/797; B60L 53/30; B60L 53/62; G01R 19/16576; G01R 23/005; H02M 1/4208

(57) ABSTRACT

The invention relates to a method, implemented by a system for controlling a two-way synchronous rectifier connected to a multi-phase AC voltage source, for detecting the presence or the absence of a neutral conductive line in the voltage source, the method comprising the following steps of:
measuring (40) at least one first quantity relating to a current flowing in a DC voltage bus at the end of a pre-charging phase of the rectifier;
receiving (42) at least one second measured quantity at the end of the pre-charging phase of the rectifier;
comparing (44) said at least one first measured quantity to a threshold value based on the second measured quantity; and
depending on the result of the comparison (44), detecting (46, 48) the presence or the absence of a neutral conductive line in the voltage source.

### CROSS-REFERENCE TO RELATED APPLICATIONS

This is the U.S. National Phase application of PCT/EP2024/065869, filed Jun. 10, 2024, which claims priority to French Patent Application No. 2305948, filed Jun. 13, 2023, the disclosures of these applications being incorporated herein by reference in their entireties for all purposes.

### FIELD OF THE INVENTION

The invention relates to a method, implemented by a system for controlling a two-way synchronous rectifier connected to a multi-phase AC voltage source, for detecting the presence or the absence of a neutral conductive line in the multi-phase AC voltage source. Preferably, the multi-phase AC voltage source is a three-phase sinusoidal electric current power supply network. The invention further relates to an assembly comprising a two-way synchronous rectifier and a system for controlling the two-way synchronous rectifier configured to implement the steps of such a method. The invention also relates to an electric charger for an electric or hybrid vehicle, comprising such an assembly, as well as to an electric or hybrid vehicle, notably a motor vehicle, comprising such an electric charger.

### BACKGROUND OF THE INVENTION

Electric chargers for electric or hybrid vehicles are known from the prior art, which chargers are placed on board such a vehicle and are intended to be connected to an electric charging terminal or station, which is connected to a sinusoidal electric voltage source (such as a three-phase electric power supply network) for electrically powering the vehicle. Such an electric charger conventionally comprises a two-way synchronous rectifier able to convert a first AC voltage into a second DC voltage, a system for controlling the two-way synchronous rectifier, as well as a converter configured to convert the second DC voltage into a third DC voltage at high frequency. The two-way synchronous rectifier comprises an active power factor correction stage and a DC voltage bus connected at the output of the active power factor correction stage. The active power factor correction stage allows power to be transferred between the sinusoidal electrical voltage source and the DC voltage bus. The synchronous rectifier is referred to as “two-way”, because it allows the electric current to flow in both directions by controlling reversible controllable electronic switches (as opposed to diodes, for example) acting in switching branches of the rectifier, with the direction of flow of the current depending on the power budget produced by the controller of the voltage regulation loop acting to maintain the DC voltage bus at its nominal voltage:
if current originating from the DC-DC converter reaches the DC voltage bus, the voltage increases and the controller acts in order to transition the current in phase opposition to the input voltage in order to discharge the DC voltage bus;
conversely, if the DC-DC converter draws current, the voltage loop controller draws current from the power supply network and the current is in phase with the input voltage.

The high-frequency DC-DC converter (typically a chopper) is connected at the output of the rectifier.

Preferably, the electric charger is compatible with any multi-phase AC electrical power supply system or network (connected to the electric charging terminal or station), whether or not the latter has a neutral conductive line. However, the presence or the absence of a neutral conductive line in the power supply system or network significantly affects the strategy for controlling the active correction stage of the two-way synchronous rectifier, implemented by the control system. Indeed, depending on whether or not a neutral conductive line is present in the power supply system or network, the strategies for controlling the active correction stage of the rectifier are completely different in terms of their implementation. For example, when a neutral conductive line is present, a phase-by-phase control strategy of the “a, b, c” type is typically used. By contrast, when the neutral conductive line is absent, a vector control of the “dq0” type is advantageously used. Furthermore, when the neutral conductive line is absent from the power supply network, the strategy for controlling the rectifier implemented by the control system must include special functions, which become unnecessary when the neutral conductive line is present (then unnecessarily increasing the computation load when no means for detecting the presence or the absence of the neutral conductive line are provided). Such special functions notably include:
compensation of the homopolar component of the electric current; and
injection of the third harmonic of the current to allow the active correction stage of the two-way synchronous rectifier to start, and to allow the high-frequency converter to operate in boost mode.

Finally, and especially, balancing the load from one phase to the next is not possible when the neutral conductive line is not connected to the electric charger, whereas this functionality must be provided when the neutral conductive line is connected to the electric charger (in order to comply with the normative requirements).

However, until now, there has been no requirement to cause the electric charging terminal or station to supply the electric charger with information relating to the presence or the absence of a neutral conductive line in the multi-phase AC voltage source. Therefore, a requirement exists to be able to provide, on the electric charger, and in particular on the two-way synchronous rectifier, information concerning the presence or the absence of a neutral conductive line in the multi-phase AC voltage source. Furthermore, such information must be available soon after the electric charger is connected to the electrical power supply network, in order to allow the system for controlling the rectifier to select the control strategy that will be used, to activate or not activate special functions such as the compensation of the homopolar component and the injection of the third harmonic of the current that are necessary at the very beginning of the charging phase in order to power the active power factor correction stage of the rectifier, and to authorize or not authorize balancing of the charge from one phase to the next.

A degraded solution that is currently used involves starting from the principle that the neutral conductive line is always absent in the multi-phase AC voltage source. Thus, the electric charger always operates as an electric charger “without neutral”. However, the main disadvantage of this solution is that such an electric charger cannot manage the maximum power that can be drawn from the phases of the voltage source, phase-by-phase. However, such a functionality can prove to be particularly useful, for example, in a context where the phases need to be completed independently of one another (if necessary by unbalancing them), allowing faster charging, or even in order to rebalance the power supply network (from one phase to the next), or even to allow distribution of the perceived power, balancing and homogenization within the active power factor correction stage of the rectifier in order to slow down the aging of the components.

An aim of the invention is to overcome the disadvantages of the prior art by proposing a method, implemented by a system for controlling a two-way synchronous rectifier connected to a multi-phase AC voltage source, for detecting the presence or the absence of a neutral conductive line in the multi-phase AC voltage source, which allows the control system to precisely detect the presence or the absence of a neutral conductive line, while being able to withstand any variations in the amplitude and the frequency of the electrical voltage supplied by the voltage source.

To this end, an aspect of the invention thus relates, in its broadest sense, to a method, implemented by a system for controlling a two-way synchronous rectifier connected to a multi-phase AC voltage source, for detecting the presence or the absence of a neutral conductive line in the multiphase AC voltage source, the two-way synchronous rectifier comprising a neutral input terminal able to be connected to a neutral conductive line of the multiphase AC voltage source, an active power factor correction stage and a DC voltage bus connected at the output of the active power factor correction stage, the active power factor correction stage being provided with a plurality of switching electronic branches, at least one half-branch of each of the switching electronic branches comprising at least one switching component, the number of switching electronic branches being equal to the number of phases in the multi-phase AC voltage source, the DC voltage bus comprising two half-branches connected in series at an intermediate terminal, said intermediate terminal being connected to the neutral input terminal, the control system comprising means for measuring at least one quantity relating to a current able to flow in the DC voltage bus, the method comprising the following steps:
a step of measuring at least one first quantity relating to a current flowing in the DC voltage bus at the end of a pre-charging phase of the two-way synchronous rectifier, during which phase no switching component is controlled by the control system, said measuring step providing a first measured quantity;
a step of receiving at least one second measured quantity at the end of the pre-charging phase of the two-way synchronous rectifier;
a step of comparing said at least one first measured quantity to a threshold value based on said at least one second measured quantity; and
depending on the result of the comparison, a step of detecting the presence or the absence of a neutral conductive line in the multi-phase AC voltage source.

By virtue of the detection method according to an aspect of the invention, the system for controlling the two-way synchronous rectifier is capable of autonomously and precisely determining whether a neutral conductive line is present in the multi-phase AC voltage source, without any communication with a potential electric charging terminal or station connected to the voltage source. The detection method according to an aspect of the invention is also able to withstand any variations in the amplitude and the frequency of the electrical voltage supplied by the voltage source, and the detection advantageously can be carried out by comparing the measured quantity both with a relative threshold and with an absolute threshold. The method also can be used for an optional plausibility check concerning the presence of a neutral conductive line, which optionally would be provided by an electric charging terminal or station connected to the voltage source. Finally, the method can be easily adapted to various types of hardware configurations and to various types of available acquisitions: for example, detection based on the current (by comparing to the frequency of the current), on the voltage, or on both at the same time.

According to a first embodiment of the invention, said at least one first measured quantity is the amplitude and/or the frequency of the voltage in the DC voltage bus at the end of the pre-charging phase of the two-way synchronous rectifier, and said at least one second measured quantity is the effective amplitude U_{eff1} and/or the frequency f₁ of the voltage provided by the multi-phase AC voltage source at the end of the pre-charging phase of the two-way synchronous rectifier, with said at least one second measured quantity being provided by a third-party measurement system. This first embodiment of the invention is advantageous when a measurement of the effective amplitude and/or of the frequency of the voltage supplied by the multi-phase AC voltage source is available for the system for controlling the rectifier.

Preferably, during the step of comparing said at least one first measured quantity to a threshold value, if said at least one first measured quantity is the voltage in the DC voltage bus at the end of the pre-charging phase of the two-way synchronous rectifier, the voltage threshold value ranges between a first value equal to
\sqrt{3}. \sqrt{2}. U_{eff1} and a second value equal to 2. \sqrt{2}. Ueff1, and is preferably equal to 0.5. (2+\sqrt{3})\sqrt{2}. U_{eff1}; and, if said at least one first measured quantity is the frequency of the voltage in the DC voltage bus at the end of the pre-charging phase of the two-way synchronous rectifier, the frequency threshold value ranges between a first value equal to 3. f₁ and a second value equal to 6. f₁, and is preferably equal to 4.5. f₁.

According to a particular technical feature of this first embodiment, if said at least one first measured quantity is the voltage in the DC voltage bus at the end of the pre-charging phase of the two-way synchronous rectifier, the presence of a neutral conductive line in the multi-phase AC voltage source is detected if, during the comparison step, the measured value of the voltage in the DC voltage bus at the end of the pre-charging phase is greater than said voltage threshold value; and, if said at least one first measured quantity is the frequency of the voltage in the DC voltage bus at the end of the pre-charging phase of the two-way synchronous rectifier, the presence of a neutral conductive line in the multi-phase AC voltage source is detected if, during the comparison step, the measured value of the frequency of the voltage in the DC voltage bus at the end of the pre-charging phase is lower than said frequency threshold value.

According to a second embodiment of the invention, the two-way synchronous rectifier further comprises a controllable electronic switch connected between the neutral input terminal and the intermediate terminal, and able to be controlled by the control system, and the step of measuring at least one first quantity relating to a current flowing in the DC voltage bus at the end of the pre-charging phase of the two-way synchronous rectifier comprises a first sub-step, during which the electronic switch is controlled so as to be in the open state, and said at least one first measured quantity is the voltage in the DC voltage bus during this first sub-step, and a second sub-step, during which the electronic switch is controlled so as to be in the closed state, with said at least one second quantity measured at the end of the pre-charging phase of the two-way synchronous rectifier being the voltage in the DC voltage bus during this second sub-step. This second embodiment of the invention is advantageous when no measurement of the effective amplitude and of the frequency of the voltage supplied by the multi-phase AC voltage source is available for the system for controlling the rectifier. Indeed, in this second embodiment, the detection of the presence or the absence of a neutral conductive line in the multi-phase AC voltage source is independent of the value of the effective amplitude and of the frequency of the voltage supplied by the voltage source.

According to a particular technical feature of this second embodiment, the presence of a neutral conductive line in the multi-phase AC voltage source is detected if, during the comparison step, the measured value of the voltage in the DC voltage bus during the first sub-step is distinct from the measured value of the voltage in the DC voltage bus during the second sub-step.

An aspect of the invention also relates to an assembly comprising a two-way synchronous rectifier and a system for controlling the two-way synchronous rectifier, the two-way synchronous rectifier being able to be connected to a multi-phase AC voltage source and comprising a neutral input terminal able to be connected to a neutral conductive line of the multiphase AC voltage source, an active power factor correction stage and a DC voltage bus connected at the output of the active power factor correction stage, the active power factor correction stage being provided with a plurality of switching electronic branches, at least one half-branch of each of the switching electronic branches comprising at least one switching component, the number of switching electronic branches being equal to the number of phases in the multi-phase AC voltage source, the DC voltage bus comprising two half-branches connected in series at an intermediate terminal, said intermediate terminal being connected to the neutral input terminal, the control system comprising means for measuring at least one quantity relating to a current able to flow in the DC voltage bus, with the system for controlling the two-way synchronous rectifier being configured to implement the steps of a method for detecting the presence or the absence of a neutral conductive line in the multi-phase AC voltage source as described above.

an aspect of the invention also relates to an electric charger for an electric or hybrid vehicle intended to be connected to an electric charging terminal or station connected to a multi-phase AC voltage source, for electrically powering said electric or hybrid vehicle, the electric charger comprising an assembly as described above.

An aspect of the invention also relates to an electric or hybrid vehicle, notably a motor vehicle, comprising an electric charger as described above.

### BRIEF DESCRIPTION OF THE DRAWINGS

Embodiments of the present invention will be described below by way of non-limiting examples and with reference to the appended figures, in which:

FIG. 1 is a schematic representation of an assembly comprising a two-way synchronous rectifier and a system for controlling the rectifier, with the control system being configured to implement the steps of a detection method according to an aspect of the present invention;

FIG. 2 is a flowchart representing a detection method according to a first embodiment of the present invention, implemented by the control system of FIG. 1;

FIG. 3 is a flowchart representing a detection method according to a second embodiment of the present invention, implemented by a system for controlling an assembly according to the invention.

### DETAILED DESCRIPTION OF EXEMPLARY EMBODIMENTS

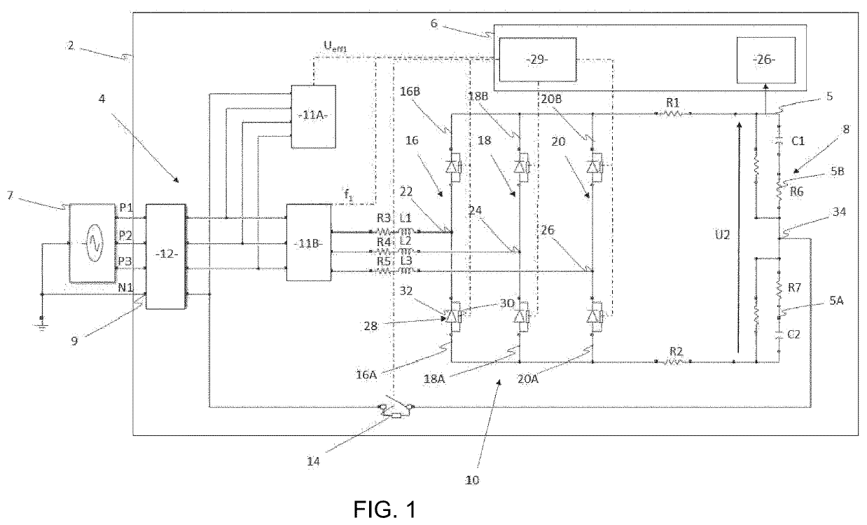

With reference to FIG. 1, an assembly 2 is illustrated comprising a two-way synchronous rectifier 4 and a system 6 for controlling the two-way synchronous rectifier 4. The assembly 2 is connected, on the one hand, to a multi-phase AC voltage source 7 (such as, for example, a three-phase electrical power supply network with neutral N1 in the particular embodiment of FIG. 1) supplying a multi-phase AC voltage (preferably sinusoidal), and, on the other hand, to a load 8 delivering DC voltage U2 between its terminals. In the particular embodiment of FIG. 1, the three-phase power supply network 7 comprises, in addition to the neutral conductive line N1, three phase conductive lines P1, P2, P3. However, sometimes the three-phase power supply network 7 does not comprise a neutral conductive line, but only phase conductive lines P1, P2, P3 (with this configuration not being shown in the figures).

The assembly 2 is typically installed inside an electric or hybrid motor vehicle, more specifically inside an electric charger intended to be connected to an electric charging terminal or station, which is connected to the AC voltage source 7, for electrically powering the vehicle (with neither the vehicle, nor the charging terminal or station, nor the charger as a whole being shown in the figures for the sake of clarity). Preferably, the DC voltage U2 allows an electrical storage battery of the vehicle to be powered, following transformation by one or more other stages of the electric charger (such as, for example, a buck and boost chopper). The assembly 2 thus provides the DC voltage U2 on an output bus 5 to which the load 8 is connected, with the value of this DC voltage U2 being, for example, of the order of 400 Vcc or 800 Vcc.

In addition to the output bus 5, the two-way synchronous rectifier 4 also comprises a neutral input terminal 9 and an active power factor correction stage 10, with the output bus 5 being connected at the output of the active power factor correction stage 10 via at least one resistor (in this case via two resistors R1, R2 in the embodiment of FIG. 1). Preferably, and as illustrated in FIG. 1, the two-way synchronous rectifier 4 also comprises an electromagnetic interference filtering stage 12, with the active power factor correction stage 10 being connected at the output of the electromagnetic interference filtering stage 12 via three inductors L1, L2, L3 and three resistors R3, R4, R5. The neutral input terminal 9 is then an input terminal of the electromagnetic interference filtering stage 12. Each pair of an inductor L1, L2, respectively L3, and of a resistor R3, R4, respectively R5, corresponds to a distinct phase conductive line P1, P2, P3, with the inductor L1, L2, L3 and the resistor R3, R4, R5 of each pair being connected in series. In the particular embodiment shown in FIG. 1, the two-way synchronous rectifier 4 also comprises a controllable electronic switch 14. As a variant, not shown in the figures, the two-way synchronous rectifier 4 may not comprise a controllable electronic switch 14.

In the particular embodiment shown in FIG. 1, two third-party measurement systems 11A, 11B allow the effective amplitude U_{eff1} and the frequency f₁ of the voltage supplied by the AC voltage source 7 to be respectively measured. As illustrated in FIG. 1, the system 11B for measuring the frequency f₁ of the current delivered by the AC voltage source 7 is connected, for example, between the active power factor correction stage 10 and the electromagnetic interference filtering stage 12. The system 11B for measuring the frequency f₁ of the current is, for example, a phase-locked loop measurement system. The two third-party measurement systems 11A, 11B are connected to the control system 6, allowing this system 6 to be provided with their measurements.

The neutral input terminal 9 is able to be connected to the neutral conductive line N1 of the AC voltage source 7, when the connection is made between the electric charger of the vehicle and the electric charging terminal or station. When the AC voltage source 7 does not comprise a neutral conductive line (which does not “recognize” the assembly 2 embedded within the electric charger, the neutral input terminal 9 is not physically connected to any element).

The electromagnetic interference filtering stage 12 is able to be connected to the AC voltage source 7 when the connection is made between the electric charger of the vehicle and the electric charging terminal or station. The electromagnetic interference filtering stage 12 comprises as many input terminals as there are phase conductive lines P1, P2, P3 in the three-phase power supply network 7. The electromagnetic interference filtering stage 12 comprises as many output terminals as there are phase conductive lines P1, P2, P3 in the three-phase power supply network 7.

The active power factor correction stage 10 comprises a plurality of electronic switching branches 16, 18, 20, in this case three electronic switching branches 16, 18, 20 in the particular embodiment of FIG. 1. Each electronic switching branch 16, 18, 20 corresponds to a distinct phase conductive line P1, P2, P3 of the three-phase power supply network 7.

Each electronic switching branch 16, 18, 20 comprises two switching half-branches 16A, 16B; 18A, 18B; 20A, 20B connected in series in an intermediate terminal 22, 24, 26. Each intermediate terminal 22, 24, 26 is connected to one end of one of the inductors L1, L2, L3. Each switching half-branch 16A, 16B, 18A, 18B, 20A, 20B comprises a switching component 28. As a variant, not shown, each half-branch 16A, 16B, 18A, 18B, 20A, 20B comprises a number N2 of switching components 28, with N2 being an integer greater than or equal to two. The switching of the switching components 28 is controlled by a control unit 29 of the control system 6. The control unit 29 is also able to control the switching of the controllable electronic switch 14, as will be described hereafter.

As is known per se, each switching component 28 is two-way for current and one-way for voltage. Each switching component 28 comprises a controllable electronic switch 30 and a diode 32 connected antiparallel, thus ensuring two-way current flow paths. Each switch 30 is formed, for example, by an insulated gate bipolar transistor, also called IGBT. All the IGBTs 30 are identical, for example. The gate of each IGBT 30 is connected to the control system 6 in order to receive a corresponding control signal. As a variant, the IGBT 30 is replaced by any semiconductor electronic component comprising a control electrode and two conduction electrodes, such as a bipolar transistor, a field-effect transistor, a thyristor, a gate turn-off thyristor, an IGCT (Insulated Gate Commutated Thyristor), or an MCT (MOS Controlled Thyristor), for example.

The output bus 5 comprises two half-branches 5A, 5B connected in series in an intermediate terminal 34. In the particular embodiment of FIG. 1, each half-branch 5A, respectively 5B, comprises a capacitor C1, respectively C2, and a resistor R6, respectively R7, connected in series. Preferably, the capacitance value of the capacitor C1 is equal to the capacitance value of the capacitor C2, in order to balance the output bus 5. The intermediate terminal 34 is connected to the neutral input terminal 9. In the particular embodiment shown in FIG. 1, the intermediate terminal 34 is connected to the neutral input terminal 9 via the controllable electronic switch 14, which is connected in series between the neutral input terminal 9 and the intermediate terminal 34.

In addition to the control unit 29, the control system 6 comprises means 26 for measuring at least one quantity relating to a current able to flow in the DC voltage bus 5. In a first embodiment of the invention, corresponding to the configuration shown in FIG. 1, the measurement means 26 are configured to measure the amplitude and/or the frequency of the voltage in the DC voltage bus 5 at the end of a pre-charging phase of the two-way synchronous rectifier 4 (with such a phase being a natural or passive pre-charging phase, during which no switching component 28 is controlled by the control system 6). Preferably, the measurement means 26 are configured to measure both the amplitude and the frequency of the voltage in the DC voltage bus 5 at the end of the pre-charging phase of the two-way synchronous rectifier 4. In a second embodiment of the invention, corresponding to a configuration, not shown in the figures, whereby the control system 6 does not have the measurement of the effective amplitude U_{eff1} or of the frequency f₁ of the voltage supplied by the AC voltage source 7 (no third-party measurement systems 11A, 11B), the measurement means 26 are configured to measure the voltage in the DC voltage bus 5 at the end of the pre-charging phase of the two-way synchronous rectifier 4.

The method for detecting the presence or the absence of a neutral conductive line in the multi-phase AC voltage source 7, implemented by the system 6 for controlling the two-way synchronous rectifier 4, will now be described.

It is assumed that the two-way synchronous rectifier 4 is initially in a pre-charging phase, during which no switching component 28 is controlled by the control system 6 (the rectifier 4 then functions as a diode bridge, and the electrical voltage delivered to the DC voltage bus 5 is progressively and naturally brought to an intermediate voltage value). After the pre-charging phase, the two-way synchronous rectifier 4 then enters a “conventional” charging phase, during which the control system 6 controls the switching of the switching components 28 in the branches 16, 18, 20 (and the electrical voltage delivered to the DC voltage bus 5 is progressively brought from its intermediate value at the end of the pre-charging phase to its nominal value), with such a charging phase not being described hereafter.

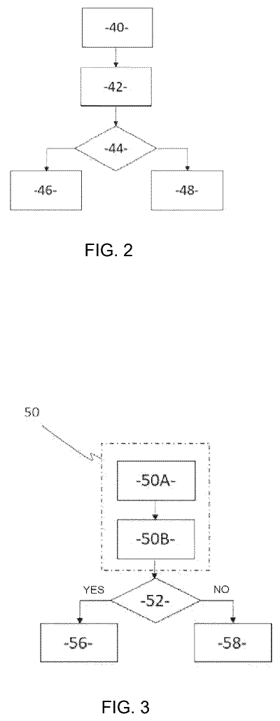

With reference to FIG. 2, the method in the first embodiment of the invention (corresponding to the configuration shown in FIG. 1) comprises an initial step 40 of the control system 6 measuring the amplitude and/or the frequency of the voltage in the DC voltage bus 5 at the end of the pre-charging phase of the two-way synchronous rectifier 4.

In this first embodiment of the invention, the method comprises a subsequent step 42, during which the system 6 for controlling the two-way synchronous rectifier 4 receives the measurement of the effective amplitude U_{eff1} and/or of the frequency f₁ of the voltage supplied by the AC voltage source 7 at the end of the pre-charging phase of the rectifier 4, with these two measurements being provided by the third-party measurement systems 11A, 11B.

The method then comprises a subsequent step 44, during which the system 6 for controlling the two-way synchronous rectifier 4 compares the measured value of the amplitude and/or of the frequency of the voltage in the DC voltage bus 5 at the end of the pre-charging phase of the two-way synchronous rectifier 4 to a threshold value. For the comparison of the voltage values, the voltage threshold value typically ranges between a first value equal to \sqrt{3}. \sqrt{2}. U_{eff1} and a second value equal to 2. \sqrt{2}. U_{eff1}, and is preferably equal to 0.5. (2+\sqrt{3})\sqrt{2}. U_{eff1}. For the comparison of the frequency values, the frequency threshold value typically ranges between a first value equal to 3. f₁ and a second value equal to 6. f₁, and is preferably equal to 4.5. f₁.

On completion of the comparison step 44, if the measured value of the voltage in the DC voltage bus 5 at the end of the pre-charging phase of the two-way synchronous rectifier 4 is greater than the voltage threshold value and/or if the measured value of the frequency of the voltage in the DC voltage bus 5 at the end of the pre-charging phase of the two-way synchronous rectifier 4 is less than the frequency threshold value, then the presence of a neutral conductive line N1 in the AC voltage source 7 is detected by the control system 6 during a final step 46 (as is the case in the configuration illustrated in FIG. 1). Otherwise, the control system 6 detects the absence of a neutral conductive line in the AC voltage source 7, during a final step 48.

Indeed, when a neutral conductive line N1 is present in the AC voltage source 7 (as is the case in the configuration illustrated in FIG. 1), the voltage in the DC voltage bus 5 at the end of the pre-charging phase of the two-way synchronous rectifier 4 is substantially equal to 2. \sqrt{2}. Ueff₁ and the frequency of the voltage in the DC voltage bus 5 at the end of the pre-charging phase of the two-way synchronous rectifier 4 is substantially equal to 3. f₁. When no neutral conductive line is present in the AC voltage source 7, the voltage in the DC voltage bus 5 at the end of the pre-charging phase of the two-way synchronous rectifier 4 is substantially equal to \sqrt{3}. \sqrt{2}. U_{eff1} and the frequency of the voltage in the DC voltage bus 5 at the end of the pre-charging phase of the two-way synchronous rectifier 4 is substantially equal to 6. f₁. Thus, by adjusting the voltage and frequency threshold values between these two pairs of limit values (preferably “midway” between these limit values), it is possible to precisely detect the presence or the absence of a neutral conductive line in the AC voltage source 7.

With reference to FIG. 3, the method in the second embodiment of the invention comprises an initial step 50 of the control system 6 measuring the voltage in the DC voltage bus 5 at the end of the pre-charging phase of the two-way synchronous rectifier 4. More specifically, the initial measuring step 50 comprises a first sub-step 50A, during which the electronic switch 14 is controlled by the control system 6 so as to be in the open state, and the control system 6 measures a first voltage value in the DC voltage bus 5 at the end of the pre-charging phase of the two-way synchronous rectifier 4. The initial measuring step 50 then comprises a second sub-step 50B, during which the electronic switch 14 is controlled by the control system 6 so as to be in the closed state, and the control system 6 measures a second voltage value in the DC voltage bus 5 at the end of the pre-charging phase of the two-way synchronous rectifier 4.

The method then comprises a subsequent step 52, during which the system 6 for controlling the two-way synchronous rectifier 4 compares the first voltage value (measured during the first sub-step 50A) to the second voltage value (measured during the second sub-step 50B).

On completion of the comparison step 52, if the first measured voltage value is distinct from the second measured voltage value, then the presence of a neutral conductive line N1 in the AC voltage source 7 is detected by the control system 6 during a final step 56. Otherwise, the control system 6 detects the absence of a neutral conductive line in the AC voltage source 7, during a final step 58.

Indeed, when a neutral conductive line N1 is present in the AC voltage source 7, the value of the voltage in the DC voltage bus 5 at the end of the pre-charging phase of the two-way synchronous rectifier 4 experiences a sudden “jump” during the closure of the electronic switch 14, due to the electrical voltage present on the neutral line N1.

By virtue of the detection method according to an aspect of the invention, the system 6 for controlling the two-way synchronous rectifier 4 is capable of autonomously and accurately determining if a neutral conductive line N1 is present in the multi-phase AC voltage source 7, without any communication with a potential electric charging terminal or station connected to the voltage source 7.

1. A method, implemented by a system for controlling a two-way synchronous rectifier connected to a multi-phase AC voltage source, for detecting the presence or the absence of a neutral conductive line in the multi-phase AC voltage source, the two-way synchronous rectifier comprising a neutral input terminal able to be connected to a neutral conductive line of the multi-phase AC voltage source, an active power factor correction stage and a DC voltage bus connected at the output of the active power factor correction stage, the active power factor correction stage being provided with a plurality of switching electronic branches, at least one half-branch of each of the switching electronic branches comprising at least one switching component, the number of switching electronic branches being equal to the number of phases in the multi-phase AC voltage source, the DC voltage bus comprising two half-branches connected in series at an intermediate terminal, said intermediate terminal being connected to the neutral input terminal, the control system comprising means for measuring at least one quantity relating to a current able to flow in the DC voltage bus, the method comprising:
a step of measuring at least one first quantity relating to a current flowing in the DC voltage bus at the end of a pre-charging phase of the two-way synchronous rectifier, during which phase no switching component is controlled by the control system, said measuring step providing a first measured quantity;
a step of receiving at least one second measured quantity at the end of the pre-charging phase of the two-way synchronous rectifier;
a step of comparing said at least one first measured quantity to a threshold value based on said at least one second measured quantity; and
depending on the result of the comparison, a step of detecting the presence or the absence of a neutral conductive line in the multi-phase AC voltage source, and
said at least one first measured quantity is the amplitude and/or the frequency of the voltage in the DC voltage bus at the end of the pre-charging phase of the two-way synchronous rectifier, and
said at least one second measured quantity is the effective amplitude U_{eff1} and/or the frequency f₁ of the voltage provided by the multi-phase AC voltage source at the end of the pre-charging phase of the two-way synchronous rectifier, with said at least one second measured quantity being provided by a third-party measurement system.

2. The method as claimed in claim 1, wherein, during the step of comparing said at least one first measured quantity to a threshold value, if said at least one first measured quantity is the voltage in the DC voltage bus at the end of the pre-charging phase of the two-way synchronous rectifier, the voltage threshold value ranges between a first value equal to \sqrt{3}. \sqrt{2}. U_{eff1} and a second value equal to 2. \sqrt{2}. U_{eff1}, and is preferably equal to 0.5. (2+\sqrt{3})\sqrt{2}. U_{eff1}; and, if said at least one first measured quantity is the frequency of the voltage in the DC voltage bus at the end of the pre-charging phase of the two-way synchronous rectifier, the frequency threshold value ranges between a first value equal to 3. f₁ and a second value equal to 6. f₁, and is preferably equal to 4.5. f₁.

3. The method as claimed in claim 2, wherein, if said at least one first measured quantity is the voltage in the DC voltage bus at the end of the pre-charging phase of the two-way synchronous rectifier, the presence of a neutral conductive line in the multi-phase AC voltage source is detected if, during the comparison step, the measured value of the voltage in the DC voltage bus at the end of the pre-charging phase is greater than said voltage threshold value; and, if said at least one first measured quantity is the frequency of the voltage in the DC voltage bus at the end of the pre-charging phase of the two-way synchronous rectifier, the presence of a neutral conductive line in the multi-phase AC voltage source is detected if, during the comparison step, the measured value of the frequency of the voltage in the DC voltage bus at the end of the pre-charging phase is lower than said frequency threshold value.

4. The method as claimed in claim 1, wherein the two-way synchronous rectifier further comprises a controllable electronic switch connected between the neutral input terminal and the intermediate terminal, and able to be controlled by the control system, and the step of measuring at least one first quantity relating to a current flowing in the DC voltage bus at the end of the pre-charging phase of the two-way synchronous rectifier comprises a first sub-step, during which the electronic switch is controlled so as to be in the open state, and said at least one first measured quantity is the voltage in the DC voltage bus during this first sub-step, and a second sub-step, during which the electronic switch is controlled so as to be in the closed state, with said at least one second quantity measured at the end of the pre-charging phase of the two-way synchronous rectifier being the voltage in the DC voltage bus during this second sub-step.

5. The method as claimed in claim 4, wherein the presence of a neutral conductive line in the multi-phase AC voltage source is detected if, during the comparison step, the measured value of the voltage in the DC voltage bus during the first sub-step is distinct from the measured value of the voltage in the DC voltage bus during the second sub-step.

6. An assembly comprising a two-way synchronous rectifier and a system for controlling the two-way synchronous rectifier, the two-way synchronous rectifier being able to be connected to a multi-phase AC voltage source and comprising a neutral input terminal able to be connected to a neutral conductive line of the multi-phase AC voltage source, an active power factor correction stage and a DC voltage bus connected at the output of the active power factor correction stage, the active power factor correction stage being provided with a plurality of switching electronic branches, at least one half-branch of each of the switching electronic branches comprising at least one switching component, the number of switching electronic branches being equal to the number of phases in the multi-phase AC voltage source, the DC voltage bus comprising two half-branches connected in series at an intermediate terminal, said intermediate terminal being connected to the neutral input terminal, the control system comprising means for measuring at least one quantity relating to a current able to flow in the DC voltage bus, wherein the system for controlling the two-way synchronous rectifier is configured to implement the steps of a method for detecting the presence or the absence of a neutral conductive line in the multi-phase AC voltage source as claimed in claim 1.

7. An electric charger for an electric or hybrid vehicle intended to be connected to an electric charging terminal or station connected to a multi-phase AC voltage source, for electrically powering said electric or hybrid vehicle, comprising an assembly as claimed in claim 6.

8. An electric or hybrid vehicle, notably a motor vehicle, comprising an electric charger as claimed in claim 7.
